(19) United States
(12) Patent Application Publication
(10) Pub. No.: US 2026/0341346 A1
(43) Pub. Date: Oct. 29, 2026

(54) COMPACT MEMORY CELLS

(71) Applicant: Microsemi SoC Corp., Chandler, AZ (US)

(72) Inventors: Derek Lam, Milpitas, CA (US); Fethi Dhaoui, Mesa, AZ (US); John Mccollum, Orem, UT (US)

(73) Assignee: Microsemi SoC Corp., Chandler, AZ (US)

(21) Appl. No.: 19/304,031

(22) Filed: Aug. 19, 2025

Related U.S. Application Data
(60) Provisional application No. 63/794,017, filed on Apr. 24, 2025.

(51) Int. Cl. G11C 11/419

(52) U.S. Cl. CPC G11C 11/419

(57) ABSTRACT

Technologies for compact memory cells are disclosed. In one example, a memory cell include two PMOS transistors used to read the state of the memory cell. The state of the memory cell controls the gate of one of the PMOS transistors, so reading the memory cell does not disturb the memory cell. Using PMOS transistors to read the memory cell allows for a more compact configuration for the memory cells. The memory cells may be used for any suitable purpose, such as memory cells for a configuration of a field-programmable gate array (FPGA).

### CROSS-REFERENCE TO RELATED APPLICATION

This application claims the benefit under 35 U.S.C. § 119(e) of U.S. Provisional Patent Application Ser. No. 63/794,017, filed Apr. 24, 2025, entitled “COMPACT MEMORY CELLS,” the entirety of which application is incorporated by reference herein.

### TECHNICAL FIELD

The present disclosure relates generally to a memory cell, and more specifically to a compact memory cell for a field-programmable gate array (FPGA) configuration memory cell.

### BACKGROUND

SRAM memory cells typically have a configuration with six transistors. The memory cells are written to and read from using the same bit lines and word lines connected to pass gates. In some cases, the pass gates are engineered to reduce disturbance from read operations and to ensure that write operations are performed successfully.

### SUMMARY OF THE INVENTION

Aspects of various examples include using additional transistors to read from the memory cell, which prevents a read operation from disturbing the memory cell. Because the pass gates are not used to read the memory cell, the approach can also provide more margin for write operations. In one example, a memory cell may use four NMOS gates and four PMOS gates. Such a configuration may be well-suited for fabrication operations where the channels for NMOS and PMOS gates are created in pairs, and an unused gate will result in underutilized silicon.

### BRIEF DESCRIPTION OF THE DRAWINGS

FIG. 1 is a simplified drawing of one example of a circuit for a memory cell with separate transistors for reading the memory cell without disturbing the memory cell.

FIG. 2 is a simplified drawing of one example of a circuit for a memory cell with separate transistors for reading the memory cell without disturbing the memory cell.

FIG. 3 is a simplified drawing of one example of a circuit for a memory cell with separate transistors for reading the memory cell without disturbing the memory cell.

FIG. 4 is a simplified drawing of one example of a circuit for a memory cell with separate transistors for reading the memory cell without disturbing the memory cell.

FIG. 5 illustrates an example field-programmable gate array device that may include one or more memory cells in accordance with examples disclosed herein.

FIG. 6 is a simplified drawing of one example of a circuit for a memory cell with separate transistors for reading the memory cell without disturbing the memory cell.

FIG. 7 is a simplified drawing of one example of a circuit for a memory cell with separate transistors for reading the memory cell without disturbing the memory cell.

FIG. 8 is a simplified drawing of one example of a circuit for a memory cell with separate transistors for reading the memory cell without disturbing the memory cell.

FIG. 9 illustrates an example integrated circuit device that may include one or more components in accordance with examples disclosed herein.

FIG. 10 is a simplified block diagram of at least one example of a compute device that may include the circuit of FIG. 1.

### DETAILED DESCRIPTION

The approach disclosed herein addresses the large cell area and the long process development associated with memory cells based on devices supported in standard logic process, particularly in regard to compact FPGA configuration memory. By adopting standard logic process, product development effort and time can be reduced considerably. Such an approach can yield 1 to 2 years product development saving. Use of standard logic devices reduces the cell area by up to three times compared to other approaches. Using three bit lines and two word lines (or two bit lines and two word lines) allows decoupling of the write and read operation for high yield, as described in more detail below.

In the following description, specific details are set forth, but examples of the technologies described herein may be practiced without these specific details. Well-known circuits, structures, and techniques have not been shown in detail to avoid obscuring an understanding of this description. Phrases such as “an example,” “various examples,” “some examples,” and the like may include features, structures, or characteristics, but not every example necessarily includes the particular features, structures, or characteristics.

Some examples may have some, all, or none of the features described for other examples. “First,” “second,” “third,” and the like describe a common object and indicate different instances of like objects being referred to. Such adjectives do not imply objects so described must be in a given sequence, either temporally or spatially, in ranking, or any other manner.

“Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to examples of the present disclosure, are synonymous.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, a die may be considered to be adjacent a substrate if there are no layers or components between the die and the substrate, although there can be, without limitation, pads or solder balls between the substrate and the die, with the die and the substrate still considered to be adjacent. As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation, location, or both orientation and location of, without limitation, layers, components or portions of components, within a consistent but arbitrary frame of reference, which is made clear by reference to the text and the associated Figures describing the, without limitation, layers, component or portions of components under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or the same numbers may be used to designate the same or similar parts in different figures. The use of similar or the same numbers in different figures does not mean all figures including similar or the same numbers constitute a single or same example. Like numerals having different letter suffixes may represent different instances of similar components. The drawings illustrate generally, by way of example, but not by way of limitation, various examples discussed in the present document.

In the following description, for purposes of explanation, numerous specific details are set forth in order to provide a thorough understanding thereof. It may be evident, however, that the novel examples can be practiced without these specific details. In other instances, well-known structures and devices are shown in block diagram form in order to facilitate a description thereof. The intention is to cover all modifications, equivalents, and alternatives within the scope of the claims.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a, without limitation, trait or feature means that all of the items in the list possess the stated or recited trait or feature. For example, the phrase “individual of A, B, or C, comprise a sidewall” or “respective of A, B, or C, comprise a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed examples, alone and in various combinations and subcombinations with one another. The disclosed methods, apparatuses, and systems are not limited to any specific aspect or feature or combination thereof, nor do the disclosed examples require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

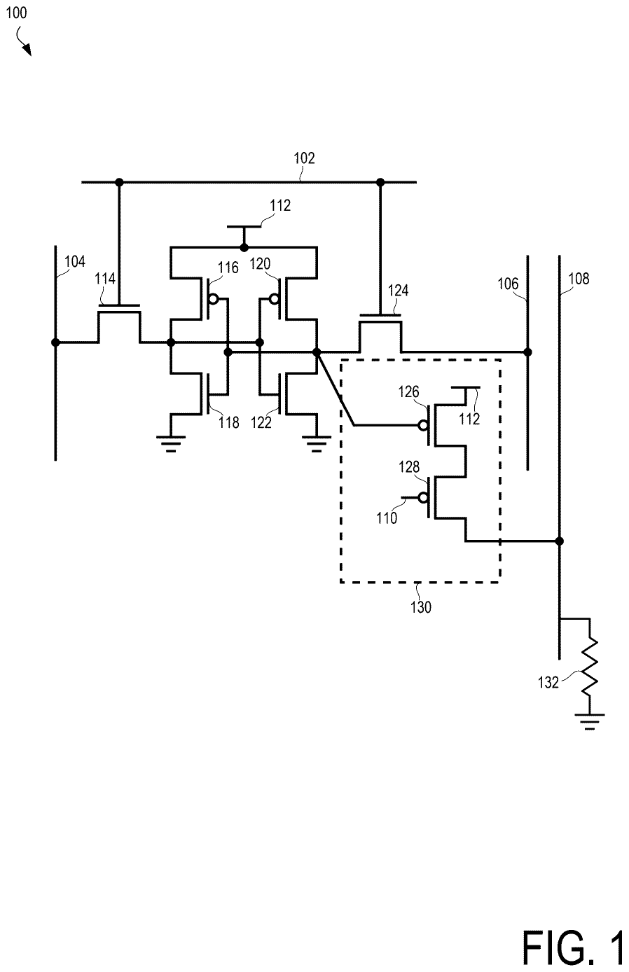

Referring now to FIG. 1, in various examples, a memory cell 100 includes a word line 102, a bit line 104, a bit line bar 106, a bit line read 108, a word line read 110, a V_{DD} voltage source 112, an NMOS transistor 114 for a pass gate, a PMOS transistor 116 for a pull-up transistor, an NMOS transistor 118 for a pull-down transistor, a PMOS transistor 120 for a pull-up transistor, an NMOS transistor 122 for a pull-down transistor, an NMOS transistor 124 for a pass gate, a PMOS transistor 126 to control a connection from V_{DD} to the bit line read 108 based on value stored in the memory cell, and a PMOS transistor 128 for the word line read 110 to control the connection from the transistor 126 to the bit line read 108. The read transistors 126, 128 are part of read circuitry 130 that can read the state of the memory cell without a risk of disturbing the state of the memory cell.

In use, to write the memory cell, word line write 102 is used to open the pass gates 114, 124, and the values on the bit line 104 and bit line bar 106 is used to write a value to the memory cell. To read the memory cell, the word line read 110 applies a low voltage to the transistor 128 to allow current to pass through it. If the state of the memory cell is “high,” then the voltage on the gate of the PMOS transistor 126 will be low (as the gate of the PMOS transistor 126 is connected to the same part of the memory cell as the bit line bar 106). The transistor 126 will allow current from V_{DD} to pass through the transistor 126 and the transistor 128, putting a high voltage on bit line read 108. If the state of the memory cell is “low,” then the voltage on the gate of the PMOS transistor 126 will be high. The bit line read 108 will then be isolated from V_{DD}, and bit line read 108 will be pulled down to low voltage using a pull-down connection to ground, such as by using a pull-down resistor 132.

In a standard 6-transistor memory cell (e.g., a memory cell without the separate read circuitry 130), the pass gates 114, 124 are used to both read and write the memory cell. In a write operation, the current through the pass gates 114, 124 driven by the bit lines 104, 106 must be enough to overwrite the value stored in the memory cell. In a read operation, the current through the pass gates 114, 124 driven by the pull-up transistors 116, 120 and pull-down transistors 118, 122 must not be enough to change the value stored in the memory cell. The balance between these two requirements can require fine tuning of parameters of the pass gates 114, 124, such as the channel width. However, in some fabrication processes, such as with modern fin FETs, tuning those parameters of transistors cannot be done as easily due to process design rules.

In contrast, with separate read circuitry 130, the pass gates 114, 124 can be tuned to have a large write buffer without any concern from read disturbances, since the read operations are done using the separate read circuitry 130. For example, the pass gates 114, 124 may have a relatively low threshold voltage, and the pull-up transistors 116, 120 and pull-down transistors 118, 122 may have a relatively high threshold voltage. The high threshold voltage on the pull-up transistors 116, 120 and pull-down transistors 118, 122 can also reduce the static power usage.

In various examples, the NMOS transistors 114, 118, 122, 124 and the PMOS transistors 116, 120, 126, 128 are created using a process which forms doped wells for NMOS and PMOS transistors in pre-defined areas, such as areas defined in a process design kit or design rule manual from a semiconductor foundry. If a particular area with a semiconductor well defined for, e.g., a PMOS transistor is not used for a PMOS transistor, it cannot be used for any transistor. As a result, for an array of typical six-transistor (6T) memory cells with four NMOS transistors and two PMOS transistors, there is space for two additional PMOS transistors for each memory cell. For that reason, using PMOS transistors 128, 126 for the read circuitry rather than two NMOS transistors can significantly reduce the total area required for a memory cell. For similar reasons, the eight transistor design shown in FIG. 1, with four n-channel transistors and four p-channel transistors, can take up a similar amount of area on a die as a six transistor design with four n-channel transistors and two p-channel transistors, under certain design rules.

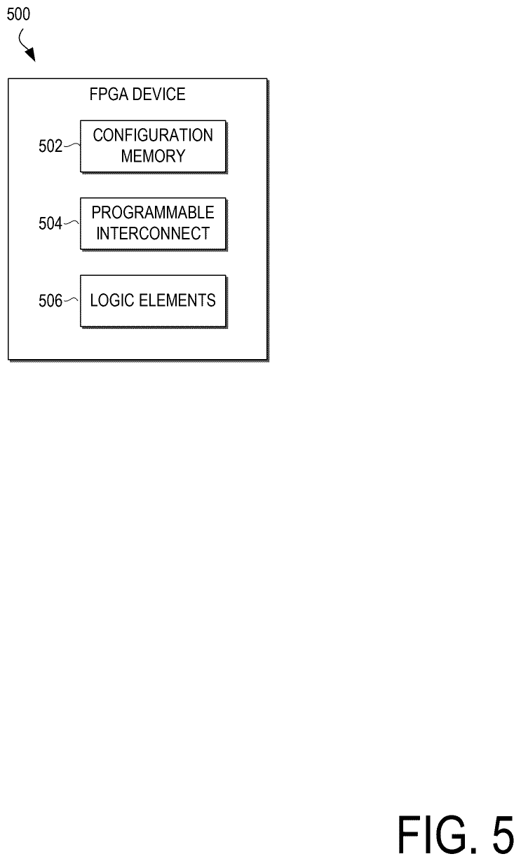

In some examples, the memory cell 100 (or the memory cells 200, 300, 400 described below or any combination thereof) may be included as part of a configuration memory 502 of an FPGA device 500, as described below in more detail in regard to FIG. 5. In some examples, the array of memory cells 100 may have a large number of metal interconnects to them, such that the pitch between memory cells is limited by the number of metal interconnects rather than the number of transistors in the memory cells 100.

In various examples, the pull-up transistors 116, 120 and pull-down transistors 118, 122 have a low operating voltage, such as less than one volt, reducing the chance of a latch up.

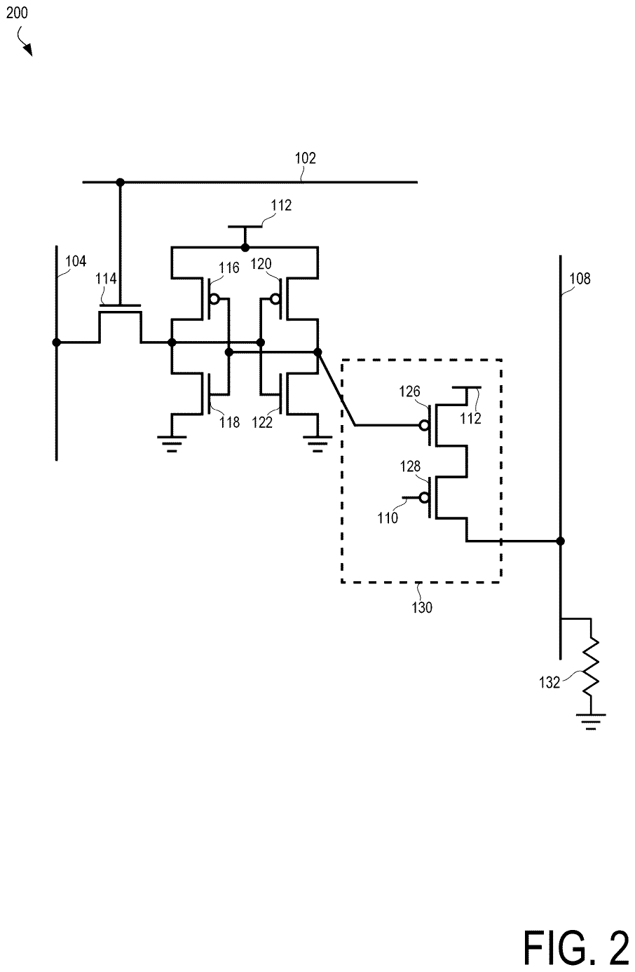

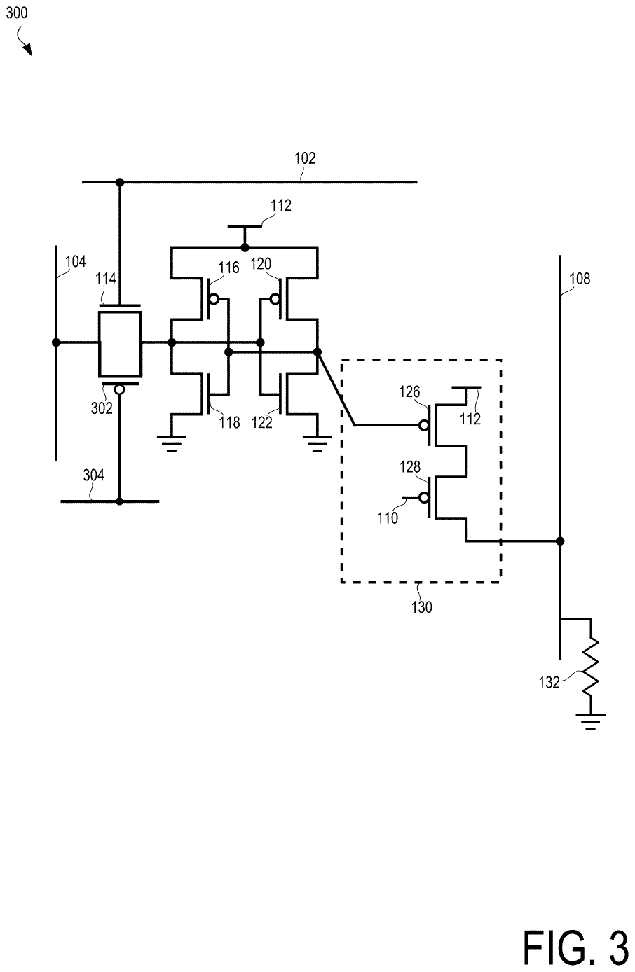

Referring now to FIG. 2, in various examples, a memory cell 200 may be similar to the memory cell 100, without the pass gate 124. In other examples, a memory cell may include an NMOS pass gate 114 and a PMOS pass gate 302, both connected to the bit line 104, and the gate of the PMOS pass gate 302 connected to a word line bar 304, as shown in FIG. 3. The memory cell 200 includes seven transistors, while the memory cell 100 includes eight transistors. Because the pass gate 114 can have a large margin for performing write operations, the memory cell 200 can still meet performance requirements with a single pass gate 114.

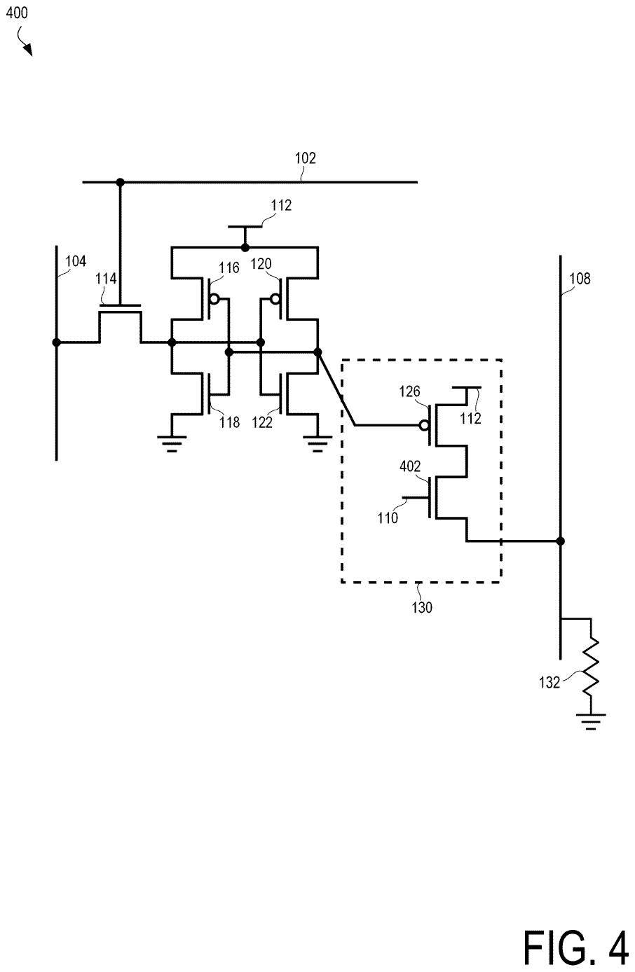

Referring now to FIG. 4, in various examples, a memory cell 400 may be similar to the memory cell 200, with an NMOS transistor 402 in place of the PMOS transistor 128. In some cases, the memory cell 300 may be more compact than the memory cells 100, 200. The memory cell 400 includes seven transistors.

Referring now to FIG. 5, in one example, a field-programmable gate array (FPGA) device 500 includes a configuration memory 502, a programmable interconnect 504, and logic elements 506. The FPGA device 500 is a fully reconfigurable integrated circuit that can be programmed with a user-defined hardware design to implement arbitrary digital functions. At power-up (or upon reconfiguration), the configuration memory 502 is loaded with a bitstream that defines how internal resources are connected and how each logic element behaves. Once configured, the programmable interconnect 504 establishes the routing paths between logic elements 506 and any embedded resources, ensuring that signals traverse the fabric according to the designer's netlist. Together, these three core blocks form a self-contained, hardware-programmable platform capable of accelerating custom algorithms, glue logic, or complete system-on-chip functions without any changes to the physical silicon.

Internally, the logic elements 506 serve as the fundamental building blocks of the FPGA fabric. Each element typically contains a small lookup table (LUT), flip-flop or latch, and a local multiplexing network, allowing it to implement combinational and sequential logic functions. The programmable interconnect 504 then ties these elements into larger structures—chains of LUTs, register files, or arithmetic units—by selectively connecting routing channels in both the horizontal and vertical directions. Configuration memory 502, often realized as an array of SRAM cells (or an embedded flash array in non-volatile devices), not only determines the logic and routing but can also store in-system patch updates or partial reconfiguration images, enabling dynamic adaptation of the FPGA at runtime.

The configuration memory 502 is a dense array of storage cells that holds the bitstream defining the behavior of every programmable resource in device 500. In various examples, the configuration memory 502 includes an array of the memory cells 100, 200, 300, 400. Each bit in the array corresponds to a configuration option: whether a particular LUT input is connected, which switch in the interconnect is closed, how an I/O buffer is biased, etc. In an SRAM-based implementation, the cells may be organized into frames and columns so that a serial or parallel configuration interface can shift in the bitstream one frame at a time. During configuration, a memory controller may apply dedicated clock and data-enable signals to load successive frames. Once loaded, an internal “apply” signal latches the new values onto the programming nodes throughout the fabric.

To ensure reliable operation, the configuration memory may incorporate error-detection and error-correction codes (ECC) at the frame level. If a single-bit upset occurs—due to radiation or electrical noise—the ECC logic can detect and correct it on the fly or flag an error for re-configuration. In some examples, the memory controller may support partial reconfiguration: updating only a subset of frames (e.g., a single column of logic elements) while the rest of the fabric continues running. Finally, security features such as bitstream encryption and authentication tags can be embedded alongside the configuration data, preventing unauthorized cloning or tampering with the loaded design.

In various examples, the memory cells 100, 200, 300, 400 in the configuration memory 502 are resilient to single bit errors (or single event upsets), multibit errors (or multiple-bit upsets), or both. Because the memory cells 100, 200, 300, 400 can be read without a chance of disturbing the memory cell 100, 200, 300, 400, a memory controller of the configuration memory 502 can perform continuous scrubbing to monitor for and correct errors. Wordline scrambling may be used to reduce the chance of multiple bit errors in a word, allowing for correction of multibit errors in physically nearby cells.

The programmable interconnect 504 provides the flexible wiring infrastructure that links together logic elements 506, configuration memory 502, and any embedded hard blocks. At its core, interconnect 504 consists of a two-dimensional grid of routing channels running in the horizontal (X) and vertical (Y) directions. Within each channel are multiple parallel “wire segments” of varying lengths—short segments that span only one tile, medium segments that span two to four tiles, and long segments that traverse the entire device. At the intersections of these channels are switch blocks, each containing a matrix of bidirectional pass-gates or transmission gates whose on/off state is controlled by bits stored in the adjacent configuration memory 502. When a given pass-gate is turned on, it electrically connects two orthogonal wire segments, creating a continuous path for a signal to propagate.

Connecting the wire segments to the pins of logic elements 506 and hard blocks are connection blocks, situated between each logic tile and the adjacent routing channels. Each connection block comprises a smaller array of pass-gates that selectively drive the input pins of a logic element from one or more nearby wire segments, or conversely, route logic-element outputs onto the routing fabric. The granularity of these connection blocks—number of track-to-pin connections and the ratio of input versus output taps—is carefully architected to balance routability, delay, and silicon area. In advanced FPGA families, the interconnect hierarchy may be augmented with direct long-line connections between frequently communicating blocks (e.g., between DSP clusters and block RAMs), and with programmable buffer insertion points to optimize signal integrity and timing closure across the die.

Each logic element 506 serves as the fundamental “cell” of device 500's fabric, combining a small, fully configurable lookup table (LUT) with at least one state-holding element and some local multiplexing. In a typical SRAM-FPGA, each element contains a six-input LUT that can be “fractured” into two smaller LUTs or used as a single 6-input truth table for combinational logic. The LUT's outputs feed a fast multiplexer that selects between the raw LUT result, a registered (clocked) version of that result, feedback from the local flip-flop, or even a constant ‘0’ or ‘1’. The flip-flop itself supports clock-enable, synchronous set/reset, and often an asynchronous clear, allowing fine-grained sequencing and pipeline staging directly within the logic fabric.

Beyond the basic LUT+flip-flop slice, logic element 506 may embed a tiny amount of distributed RAM or shift-register functionality by reusing the LUT and register infrastructure. Dedicated fast carry-chain links may run adjacent to each element, enabling high-speed arithmetic (adders, counters) by propagating carry signals with minimal delay. The local interconnect network immediately surrounding each element may provide a handful of short wires and programmable pass-gates for hooking its inputs and outputs into the larger routing fabric; this “intra-tile” connectivity determines how many signals can drive the element and how many of its outputs can fan out locally. Taken together, these resources let a single logic element implement anything from a simple gate or flip-flop to a small state machine, arithmetic bit-slice, or distributed memory bit with very high area and performance efficiency.

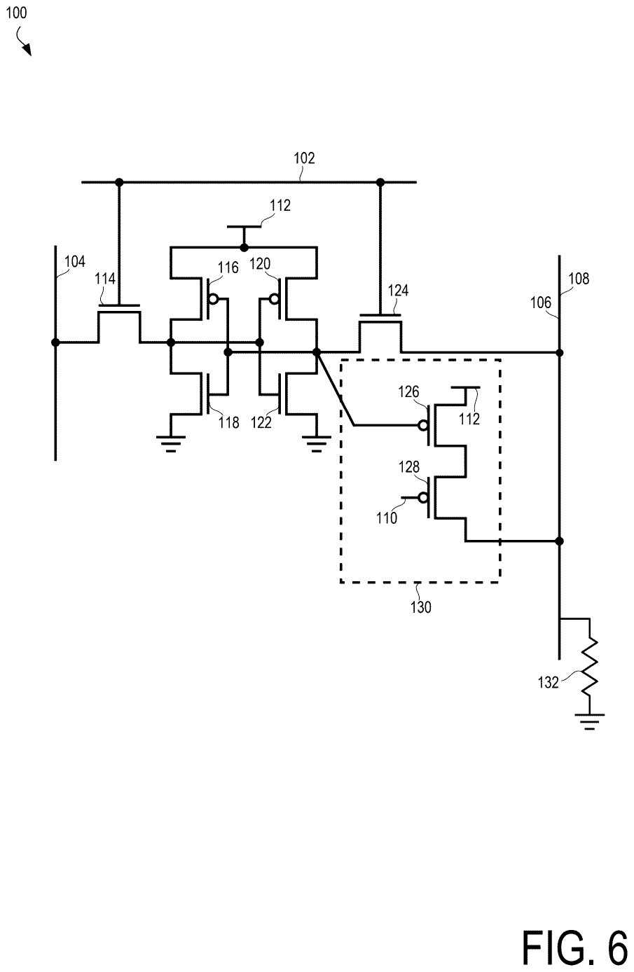

It should be appreciated that the examples described above are merely some of the possible examples, and other examples are envisioned as well. For example, the bit line bar 106 and bit line read 108 may be combined into one line, as shown in FIG. 6, in order to allow for more efficient use of metal lines. In other examples, the bit line 104 and bit line ready 108 may be combined into one line.

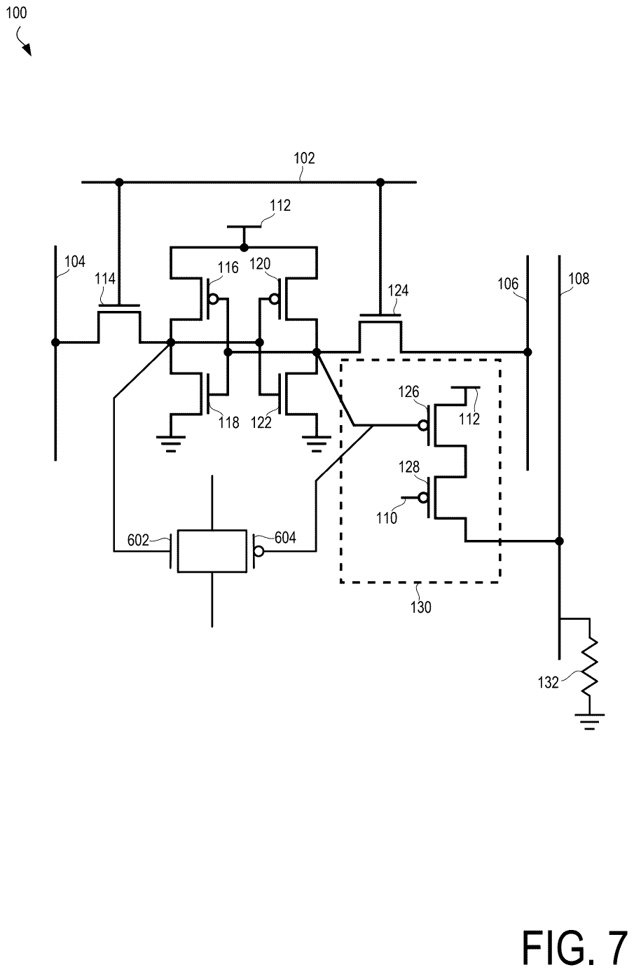

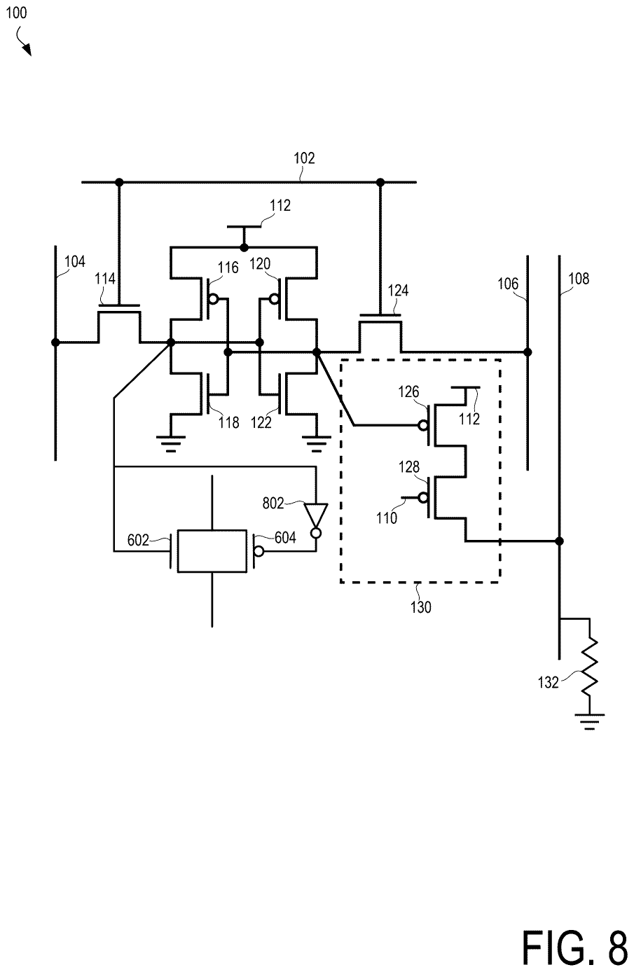

In another example, NMOS transistor 602 and PMOS transistor 604 may be connected directly to the memory cell 100, as shown in FIG. 7. The transistors 602, 604 may be connected to the Q and Q bar of, e.g., an FPGA configuration memory. The state of the memory cell 100 may directly control a look-up table (LUT) of the FPGA. The transistors 602, 604 may be positioned near the LUT, near the memory cell 100, or in another location. In the example shown in FIG. 7, the transistors 602, 604 are connected to both the part of the memory cell 100 storing the logical value as well as the part of the memory cell 100 storing the inverse logical value. In some examples, the transistors 602, 604 may both be connected to the same part of the memory cell 100, with an inverter 802 before one of the transistors 602, 604, as shown in FIG. 8.

It should be appreciated that any of the variations described above may be combined with any other suitable variation, as appropriate. For example, the bit line bar 106 and bit line read 108 may be combined into one line, as shown in FIG. 6, and transistors 602, 604 may be connected directly to the memory cell 100, as shown in FIG. 7. Generally, various examples may include or not include any suitable combination of one or more of a merged bit line bar 106 and bit line read 108 (or a merged bit line 104 and bit line read 108), transistors 602, 604 directly connected to the memory cell 100, a dual pass transistor 114, 124 or single pass transistor 114, the NMOS transistor 402 or the PMOS transistor 128, etc.

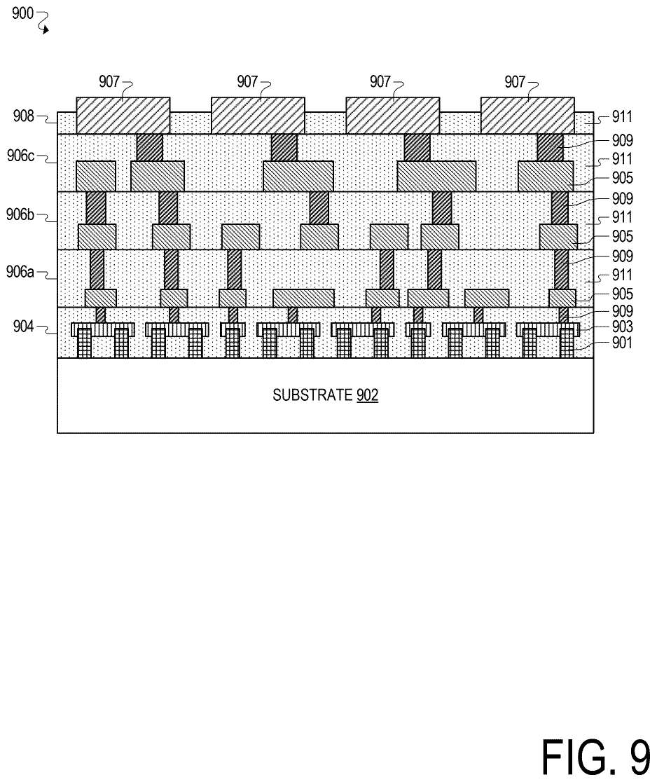

Referring now to FIG. 9, in one example, an integrated circuit (IC) device 900 is shown. The IC device 900 may include one or more memory cells 100, 200, 300, 400 in accordance with examples disclosed herein. In some examples, IC device 900 may be included in an IC die, such as a system-on-chip (SoC) die, processor die, memory die, input/output (I/O) die, or power die (e.g., power management integrated circuit (PMIC)), among other examples.

In the illustrated example, IC device 900 includes a semiconductor substrate 902, a device layer 904 over the semiconductor substrate 902, multiple internal interconnect layers 906a-c over the device layer 904, and an external interconnect layer 908 over the internal interconnect layers 906a-c (e.g., on the upper surface of IC device 900).

The semiconductor substrate 902 may include any suitable semiconductor material, including, without limitation, silicon, silicon carbide, silicon germanium, germanium, indium antimonide, lead telluride, indium arsenide, indium phosphide, gallium arsenide, gallium antimonide, or other group II-VI, III-V, or IV semiconductor materials.

The device layer 904 may include one or more semiconductor devices 901 (e.g., transistors, diodes) formed in, on, or over the semiconductor substrate 902. In some examples, the semiconductor devices 901 may include, without limitation, bipolar junction transistors (BJTs), field-effect transistors (FETs), junction field-effect transistors (JFETs), metal-oxide-semiconductor field-effect transistors (MOSFETs), double-diffused metal-oxide-semiconductor (DMOS) transistors, laterally-diffused metal-oxide-semiconductor (LDMOS) transistors, complementary metal-oxide-semiconductor (CMOS) transistors (e.g., n-type MOS (NMOS) transistors, p-type MOS (PMOS) transistors), bipolar diodes (e.g., p-n junction diodes), unipolar diodes (e.g., metal-semiconductor junction (Schottky) diodes), bipolar-CMOS-DMOS (BCD) devices (e.g., integrated BJT, CMOS, and DMOS/LDMOS transistors on a single chip for mixed-signal (analog/digital) high-power applications), or combinations thereof.

In some examples, the semiconductor devices 901 may include n-type semiconductor devices (e.g., NMOS transistors), p-type semiconductor devices (e.g., PMOS transistors), or a combination thereof.

The device layer 904 also includes conductive contacts 903 on the semiconductor devices 901 (e.g., a source, drain, or gate contact 903 coupled to the source, drain, or gate of a transistor 901), which are electrically coupled to the internal interconnect layers 906 by vias 909.

The internal interconnect layers 906a-c include conductive features 905, such as traces or pads, embedded in dielectric material 911 (e.g., dielectric buildup material such as Ajinomoto Build-Up Film (ABF)). The conductive features 905 in different interconnect layers 906a-c are electrically coupled to each other by vias 909.

The external interconnect layer 908 includes conductive contacts 907 (e.g., pads) embedded in dielectric material 911 (e.g., solder resist) on the upper surface of IC device 900. The conductive contacts 911 are electrically coupled to the internal interconnect layers 906 by vias 909. Moreover, the conductive contacts 911 can be used to electrically couple IC device 900 to another external IC device (not shown), such as an IC die, IC package, or circuit board (e.g., PCB).

The conductive features 903, 905, 907 in different layers 904, 906a-c, 908 of IC device 900 are electrically coupled to each other by vias 909. Moreover, all of the conductive features 903, 905, 907, 909 in IC device 900 may be collectively referred to as conductive routing. The conductive routing 903, 905, 907, 909 may be used to route power or signals to, from, or between semiconductor devices 901 in the device layer 904 and any external IC devices electrically coupled to the surface contacts 907.

Although a certain number of internal interconnect layers 906a-c are shown in the illustrated example, IC device 900 may include any suitable number of interconnect layers 906. In some implementations, interconnect layers 906 that are higher up in the device stack (e.g., further from the device layer 904) may be thicker than interconnect layers 906 that are lower in the device stack. In some instances, interconnect layers 906a-c may be referred to as metal layers or metallization layers. As an example, interconnect layer 906a may be referred to as the metal 0 (M0) layer, interconnect layer 906b may be referred to as the metal 1 (M1) layer, and interconnect layer 906c may be referred to as the metal 2 (M2) layer.

The dielectric material 911 in the device layer 904, the internal interconnect layers 906, and the external interconnect layer 908 may vary across the respective layers. Moreover, the conductive features 903, 905, 907, 909 in IC device 900 may be formed of any suitable conductive materials (e.g., metal).

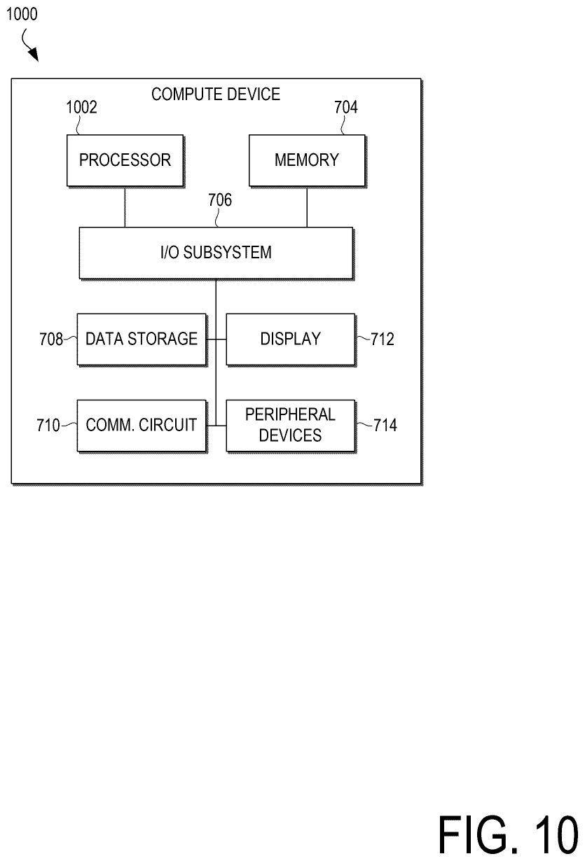

Referring now to FIG. 10, in one example, a block diagram of a compute device 1000 shows various components of the computing device 1000. The compute device 1000 may include any suitable combination of any of the various examples of memory cells 100, 200, 300, 400 disclosed herein. For example, without limitation, the memory 1004, processor 1002, or data storage 1008 include any suitable combination of any of the various examples of memory cells 100, 200, 300, 400. In some examples, the compute device 1000 may be embodied as or otherwise include a field-programmable gate array FPGA device, and the configuration memory for the FPGA device may include any suitable combination of any of the various examples of memory cells 100, 200, 300, 400.

The compute device 1000 may be embodied as any type of compute device. For example, the compute device 1000 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a network device, a router, a switch, a networked computer, a wearable computer, a handset, a messaging device, a camera device, an application-specific integrated circuit (ASIC), a field-programmable gate array (FPGA), or any other computing device.

The illustrative compute device 1000 includes one or more processors 1002, a memory 1004, an input/output (I/O) subsystem 1006, data storage 1008, a communication circuit 1010, a display 1012, and one or more peripheral devices 1014. In various examples, one or more of the illustrative components of the compute device 1000 may be incorporated in, or otherwise form a portion of, another component. For example, the memory 1004, or portions thereof, may be incorporated in the processor 1002 in various examples. In various examples, one or more of the illustrative components may be physically separated from another component. In some examples, some of the components in the illustrative compute device 1000 may be omitted.

The processor 1002 may be embodied as any type of processor capable of performing the functions described herein. For example, the processor 1002 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 1004 may be embodied as any type of volatile or non-volatile memory or data storage capable of performing the functions described herein. In operation, the memory 1004 may store various data and software used during operation of the compute device 1000 such as operating systems, applications, programs, libraries, and drivers. The memory 1004 is communicatively coupled to the processor 1002 via the I/O subsystem 1006, which may be embodied as circuitry, components, or both to facilitate input/output operations with the processor 1002, the memory 1004, and other components of the compute device 1000. For example, the I/O subsystem 1006 may be embodied as, or otherwise include, memory controller hubs, input/output control hubs, firmware devices, communication links (e.g., without limitation, point-to-point links, bus links, wires, cables, light guides, or printed circuit board traces), other components and subsystems to facilitate the input/output operations. The I/O subsystem 1006 may connect various internal and external components of the compute device 1000 to each other with use of, without limitation, any suitable connector, interconnect, bus, or protocol, such as an SoC fabric, PCIe®, USB2, USB3, USB4, NVMe®, Thunderbolt®, or the like. In various examples, the I/O subsystem 1006 may form a portion of a system-on-a-chip (SoC) and be incorporated, along with the processor 1002, the memory 1004, and other components of the compute device 1000 on a single integrated circuit chip.

The data storage 1008 may be embodied as any type of device or devices configured for the short-term or long-term storage of data. For example, the data storage 1008 may include any one or more memory devices and circuits, memory cards, hard disk drives, solid-state drives, or other data storage devices.

The communication circuit 1010 may be embodied as any type of interface capable of interfacing the compute device 1000 with other compute devices, such as over one or more wired or wireless connections. In various examples, the communication circuit 1010 may be capable of interfacing with any appropriate cable type, such as an electrical cable or an optical cable. The communication circuit 1010 may be configured to use any one or more communication technology and associated protocols (e.g., without limitation, Ethernet, Bluetooth®, Wi-Fi®, WiMAX, or near field communication (NFC)). The communication circuit 1010 may be located on silicon separate from the processor 1002, or the communication circuit 1010 may be included in a multi-chip package with the processor 1002, or even on the same die as the processor 1002. The communication circuit 1010 may be embodied as one or more add-in-boards, daughtercards, network interface cards, controller chips, chipsets, specialized components such as a field-programmable gate array (FPGA) or application-specific integrated circuit (ASIC), or other devices that may be used by the compute device 1000 to connect with another compute device. In various examples, communication circuit 1010 may be embodied as part of a system-on-a-chip (SoC) that includes one or more processors or may be included on a multichip package that also contains one or more processors. In various examples, the communication circuit 1010 may include a local processor (not shown) or a local memory (not shown) or both that are both local to the communication circuit 1010. In such examples, the local processor of the communication circuit 1010 may be capable of performing one or more of the functions of the processor 1002 described herein. Additionally or alternatively, in such examples, the local memory of the communication circuit 1010 may be integrated into one or more components of the compute device 1000 at the board level, socket level, chip level, or other levels.

The display 1012 may be embodied as any type of display on which information may be displayed to a user of the compute device 1000, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, or other display technology.

In various examples, the compute device 1000 may include other or additional components, such as those commonly found in a compute device. For example, the compute device 1000 may also have peripheral devices 1014, such as, without limitation, a keyboard, a mouse, or an external storage device. In various examples, the compute device 1000 may be connected to a dock that can interface with various devices, including peripheral devices 1014.

### EXAMPLES

Illustrative examples of the technologies disclosed herein are provided below. An example of the technologies may include any one or more, and any combination of, the examples described below.

Example 1 includes a memory cell comprising a first inverter, the first inverter comprising a first transistor and a second transistor, wherein the first transistor is an N-channel metal-oxide-semiconductor (NMOS) transistor and the second transistor is a P-channel metal-oxide-semiconductor (PMOS) transistor; a second inverter, the second inverter comprising a third transistor and a fourth transistor, wherein the third transistor is an NMOS transistor and the fourth transistor is a PMOS transistor; a pass gate, the pass gate comprising a fifth transistor; and read circuitry, the read circuitry comprising a sixth transistor and a seventh transistor, wherein at least one of the sixth transistor and the seventh transistor is a PMOS transistor, wherein an output of the first inverter is connected to a gate of the sixth transistor.

Example 2 includes the subject matter of Example 1, and wherein a source of the sixth transistor is connected to a voltage rail, wherein a drain of the sixth transistor is connected to a source of the seventh transistor, wherein a drain of the seventh transistor is connected to a read bit line, wherein a gate of the seventh transistor is connected to a read wordline.

Example 3 includes the subject matter of any of Examples 1 and 2, and wherein the sixth transistor is a PMOS transistor, wherein the seventh transistor is a PMOS transistor.

Example 4 includes the subject matter of any of Examples 1-3, and wherein the sixth transistor is a PMOS transistor, wherein the seventh transistor is an NMOS transistor.

Example 5 includes the subject matter of any of Examples 1-4, and wherein an output of the first inverter is connected to a gate of the third transistor and the fourth transistor, wherein an output of the second inverter is connected to a gate of the first transistor and the second transistor.

Example 6 includes the subject matter of any of Examples 1-5, and further including a second pass gate, the second pass gate comprising an eighth transistor, wherein a drain of the fifth transistor of the pass gate is connected to an input of the second inverter, wherein a drain of the eighth transistor of the second pass gate is connected to an input of the first inverter.

Example 7 includes the subject matter of any of Examples 1-6, and wherein PMOS transistors of the memory cell are formed in locations of a semiconductor die pre-determined to support PMOS transistors, wherein NMOS transistors of the memory cell are formed in locations of a semiconductor die pre-determined to support NMOS transistors.

Example 8 includes the subject matter of any of Examples 1-7, and wherein the pass gate further comprises an eighth transistor, wherein the fifth transistor is an NMOS transistor, wherein the eighth transistor is a PMOS transistor.

Example 9 includes the subject matter of any of Examples 1-8, and wherein an operating voltage of the memory cell is less than one volt.

Example 10 includes a system comprising the memory cell of claim 1 and a plurality of memory cells, the plurality of memory cells comprising the memory cell, the system comprising a memory controller, wherein the memory controller is to perform continuous scrubbing on the memory cell to monitor for and correct errors.

Example 11 includes the subject matter of Example 10, and wherein the plurality of memory cells implement wordline scrambling, wherein the memory controller is able to correct multi-error bits on adjacent memory cells.

Example 12 includes the subject matter of any of Examples 10 and 11, and wherein the system comprises a field-programmable gate array (FPGA), wherein the FPGA comprises a configuration memory, wherein the configuration memory comprises the plurality of memory cells.

Example 13 includes a semiconductor die comprising a memory cell, the memory cell comprising a first transistor, wherein the first transistor is an NMOS transistor, wherein a gate of the first transistor is connected to a wordline write signal, wherein a source of the first transistor is connected to a bit line signal; a second transistor, wherein the second transistor is a PMOS transistor, wherein a source of the PMOS transistor is connected to a voltage supply, wherein a drain of the second transistor is connected to a drain of the first transistor; a third transistor, wherein the third transistor is an NMOS transistor, wherein a source of the third transistor is connected to ground, wherein a drain of the third transistor is connected to the drain of the first transistor and the drain of the second transistor, wherein a gate of the third transistor is connected to a gate of the second transistor; a fourth transistor, wherein the fourth transistor is a PMOS transistor, wherein a source of the PMOS transistor is connected to the voltage supply, wherein a gate of the fourth transistor is connected to the drain of the first transistor, the drain of the second transistor, and the drain of the third transistor, a fifth transistor wherein the fifth transistor is an NMOS transistor, wherein a source of the fifth transistor is connected to ground, wherein a drain of the fifth transistor is connected to a drain of the fourth transistor, wherein a gate of the fifth transistor is connected to the gate of the fourth transistor; a sixth transistor, wherein the sixth transistor is a PMOS transistor, wherein a source of the sixth transistor is connected to the voltage supply, wherein a gate of the sixth transistor is connected the drain of the fourth transistor; and a seventh transistor, wherein a source of the seventh transistor is connected to a drain of the sixth transistor, wherein a gate of the seventh transistor is connected to a wordline read signal, wherein a drain of the seventh transistor is connected to a read bit line.

Example 14 includes the subject matter of Example 13, and wherein the memory cell further comprises an eighth transistor, wherein the eighth transistor is an NMOS transistor, wherein a gate of the eighth transistor is connected to the wordline write signal, wherein a source of the eighth transistor is connected to a bit line bar signal.

Example 15 includes the subject matter of any of Examples 13 and 14, and wherein the seventh transistor is an NMOS transistor.

Example 16 includes the subject matter of any of Examples 13-15, and wherein the seventh transistor is a PMOS transistor.

Example 17 includes the subject matter of any of Examples 13-16, and wherein PMOS transistors of the memory cell are formed in locations of the semiconductor die pre-determined to support PMOS transistors, wherein NMOS transistors of the memory cell are formed in locations of the semiconductor die pre-determined to support NMOS transistors.

Example 18 includes the subject matter of any of Examples 13-17, and wherein the second transistor and the third transistor form a first inverter, wherein the fourth transistor and the fifth transistor form a second inverter.

Example 19 includes the subject matter of any of Examples 13-18, and wherein the first transistor functions as a pass gate.

Example 20 includes the subject matter of any of Examples 13-19, and further including a pass gate, wherein the pass gate comprises an NMOS transistor and a PMOS transistor.

Example 21 includes the subject matter of any of Examples 13-20, and wherein an operating voltage of the second transistor, third transistor, fourth transistor, and fifth transistor is less than one volt.

Example 22 includes a system comprising the semiconductor die of claim 18, the semiconductor die comprises a plurality of memory cells, the plurality of memory cells comprising the memory cell, the system comprising a memory controller, wherein the memory controller is to perform continuous scrubbing on the memory cell to monitor for and correct errors.

Example 23 includes the subject matter of Example 22, and wherein the plurality of memory cells implement wordline scrambling, wherein the memory controller is able to correct multi-error bits on adjacent memory cells.

Example 24 includes the subject matter of any of Examples 22 and 23, and wherein the system comprises a field-programmable gate array (FPGA), wherein the FPGA comprises a configuration memory, wherein the configuration memory comprises the plurality of memory cells.

Example 25 includes a memory cell comprising a plurality of transistors to store a bit of memory; and read circuitry to read the bit of memory, the read circuitry comprising a PMOS transistor, wherein a signal representing a state of the bit of memory is to connect to a gate of the PMOS transistor.

Example 26 includes the subject matter of Example 25, and wherein PMOS transistors of the memory cell are formed in locations of a semiconductor die pre-determined to support PMOS transistors, wherein NMOS transistors of the memory cell are formed in locations of a semiconductor die pre-determined to support NMOS transistors.

Example 27 includes the subject matter of any of Examples 25 and 26, and wherein the plurality of transistors comprises five transistors, wherein the read circuitry comprises two PMOS transistors.

Example 28 includes the subject matter of any of Examples 25-27, and wherein the plurality of transistors comprises six transistors, wherein the read circuitry comprises two PMOS transistors.

Example 29 includes the subject matter of any of Examples 25-28, and wherein the plurality of transistors comprises five transistors, wherein the read circuitry comprises an NMOS transistor.

Example 30 includes the subject matter of any of Examples 25-29, and wherein the plurality of transistors comprises six transistors, wherein the read circuitry comprises an NMOS transistor.

Example 31 includes the subject matter of any of Examples 25-30, and further including a pass gate, wherein the pass gate comprises an NMOS transistor and a PMOS transistor.

Example 32 includes the subject matter of any of Examples 25-31, and wherein an operating voltage of the plurality of transistors is less than one volt.

Example 33 includes a system comprising the memory cell of claim 25 and a plurality of memory cells, the plurality of memory cells comprising the memory cell, the system comprising a memory controller, wherein the memory controller is to perform continuous scrubbing on the memory cell to monitor for and correct errors.

Example 34 includes the subject matter of Example 33, and wherein the plurality of memory cells implement wordline scrambling, wherein the memory controller is able to correct multi-error bits on adjacent memory cells.

Example 35 includes the subject matter of any of Examples 33 and 34, and wherein the system comprises a field-programmable gate array (FPGA), wherein the FPGA comprises a configuration memory, wherein the configuration memory comprises the plurality of memory cells.

1. A memory cell comprising:
a first inverter, the first inverter comprising a first transistor and a second transistor, wherein the first transistor is an N-channel metal-oxide-semiconductor (NMOS) transistor and the second transistor is a P-channel metal-oxide-semiconductor (PMOS) transistor;
a second inverter, the second inverter comprising a third transistor and a fourth transistor, wherein the third transistor is an NMOS transistor and the fourth transistor is a PMOS transistor;
a pass gate, the pass gate comprising a fifth transistor; and
read circuitry, the read circuitry comprising a sixth transistor and a seventh transistor, wherein at least one of the sixth transistor and the seventh transistor is a PMOS transistor, wherein an output of the first inverter is connected to a gate of the sixth transistor.

2. The memory cell of claim 1, wherein a source of the sixth transistor is connected to a voltage rail, wherein a drain of the sixth transistor is connected to a source of the seventh transistor, wherein a drain of the seventh transistor is connected to a read bit line, wherein a gate of the seventh transistor is connected to a read wordline.

3. The memory cell of claim 2, wherein the sixth transistor is a PMOS transistor, wherein the seventh transistor is a PMOS transistor.

4. The memory cell of claim 2, wherein the sixth transistor is a PMOS transistor, wherein the seventh transistor is an NMOS transistor.

5. The memory cell of claim 1, wherein an output of the first inverter is connected to a gate of the third transistor and the fourth transistor, wherein an output of the second inverter is connected to a gate of the first transistor and the second transistor.

6. The memory cell of claim 1, further comprising a second pass gate, the second pass gate comprising an eighth transistor, wherein a drain of the fifth transistor of the pass gate is connected to an input of the second inverter, wherein a drain of the eighth transistor of the second pass gate is connected to an input of the first inverter.

7. The memory cell of claim 1, wherein PMOS transistors of the memory cell are formed in locations of a semiconductor die pre-determined to support PMOS transistors, wherein NMOS transistors of the memory cell are formed in locations of a semiconductor die pre-determined to support NMOS transistors.

8. The memory cell of claim 1, wherein the pass gate further comprises an eighth transistor, wherein the fifth transistor is an NMOS transistor, wherein the eighth transistor is a PMOS transistor.

9. The memory cell of claim 1, wherein an operating voltage of the memory cell is less than one volt.

10. A system comprising the memory cell of claim 1 and a plurality of memory cells, the plurality of memory cells comprising the memory cell, the system comprising a memory controller, wherein the memory controller is to perform continuous scrubbing on the memory cell to monitor for and correct errors.

11. The system of claim 10, wherein the plurality of memory cells implement wordline scrambling, wherein the memory controller is able to correct multi-error bits on adjacent memory cells.

12. The system of claim 10, wherein the system comprises a field-programmable gate array (FPGA), wherein the FPGA comprises a configuration memory, wherein the configuration memory comprises the plurality of memory cells.

13. A semiconductor die comprising a memory cell, the memory cell comprising:
a first transistor, wherein the first transistor is an NMOS transistor, wherein a gate of the first transistor is connected to a wordline write signal, wherein a source of the first transistor is connected to a bit line signal;
a second transistor, wherein the second transistor is a PMOS transistor, wherein a source of the PMOS transistor is connected to a voltage supply, wherein a drain of the second transistor is connected to a drain of the first transistor;
a third transistor, wherein the third transistor is an NMOS transistor, wherein a source of the third transistor is connected to ground, wherein a drain of the third transistor is connected to the drain of the first transistor and the drain of the second transistor, wherein a gate of the third transistor is connected to a gate of the second transistor;
a fourth transistor, wherein the fourth transistor is a PMOS transistor, wherein a source of the PMOS transistor is connected to the voltage supply, wherein a gate of the fourth transistor is connected to the drain of the first transistor, the drain of the second transistor, and the drain of the third transistor,
a fifth transistor wherein the fifth transistor is an NMOS transistor, wherein a source of the fifth transistor is connected to ground, wherein a drain of the fifth transistor is connected to a drain of the fourth transistor, wherein a gate of the fifth transistor is connected to the gate of the fourth transistor;
a sixth transistor, wherein the sixth transistor is a PMOS transistor, wherein a source of the sixth transistor is connected to the voltage supply, wherein a gate of the sixth transistor is connected the drain of the fourth transistor; and
a seventh transistor, wherein a source of the seventh transistor is connected to a drain of the sixth transistor, wherein a gate of the seventh transistor is connected to a wordline read signal, wherein a drain of the seventh transistor is connected to a read bit line.

14. The semiconductor die of claim 13, wherein the memory cell further comprises an eighth transistor, wherein the eighth transistor is an NMOS transistor, wherein a gate of the eighth transistor is connected to the wordline write signal, wherein a source of the eighth transistor is connected to a bit line bar signal.

15. The semiconductor die of claim 13, wherein the seventh transistor is an NMOS transistor.

16. The semiconductor die of claim 13, wherein the seventh transistor is a PMOS transistor.

17. The semiconductor die of claim 13, wherein PMOS transistors of the memory cell are formed in locations of the semiconductor die pre-determined to support PMOS transistors, wherein NMOS transistors of the memory cell are formed in locations of the semiconductor die pre-determined to support NMOS transistors.

18. The semiconductor die of claim 13, wherein the second transistor and the third transistor form a first inverter, wherein the fourth transistor and the fifth transistor form a second inverter.

19. A memory cell comprising:
a plurality of transistors to store a bit of memory; and
read circuitry to read the bit of memory, the read circuitry comprising a PMOS transistor, wherein a signal representing a state of the bit of memory is to connect to a gate of the PMOS transistor.

20. The memory cell of claim 19, wherein PMOS transistors of the memory cell are formed in locations of a semiconductor die pre-determined to support PMOS transistors, wherein NMOS transistors of the memory cell are formed in locations of a semiconductor die pre-determined to support NMOS transistors.
